(19) United States
(12) Patent Application Publication
(10) Pub. No.: US 2023/0236265 A1
(43) Pub. Date: Jul. 27, 2023

(54) METHODS, SYSTEMS AND TERMINAL DEVICES FOR ANALYZING STATES OF BATTERY PACKS IN BATTERY CLUSTER

(71) Applicant: SHANGHAI MAKESENS ENERGY STORAGE TECHNOLOGY CO., LTD., Shanghai (CN)

(72) Inventors: Weikun Wu, Shanghai (CN); Peng Ding, Shanghai (CN); Danfei Gu, Shanghai (CN); Pingchao Hao, Shanghai (CN); Pei Song, Shanghai (CN); Xiao Yan, Shanghai (CN); Enhai Zhao, Shanghai (CN); Xiaohua Chen, Shanghai (CN); Guopeng Zhou, Shanghai (CN); Mingchen Jiang, Shanghai (CN); Longfei Ye, Shanghai (CN)

(21) Appl. No.: 18/101,237

(22) Filed: Jan. 25, 2023

(30) Foreign Application Priority Data
Jan. 26, 2022 (CN) 202210095433.4

(51) Int. Cl. G01R 31/396; G01R 31/367; G01R 31/392; G01R 31/388

(52) U.S. Cl. CPC G01R 31/396; G01R 31/367; G01R 31/392; G01R 31/388

(57) ABSTRACT

The invention provides a method, a system and a terminal device for analyzing states of battery packs in a battery cluster. The method includes acquiring cell voltages of each battery pack in the battery cluster within a preset time; performing data cleaning on the acquired cell voltages; calculating a voltage standard score of each cell based on the cell voltages after data cleaning; calculating a mean value and a standard deviation of said voltage standard score; for each battery pack, plotting scattered points based on the mean value and the standard deviation, and performing closed curve fitting to the scattered points to obtain a closed curve; and analyzing the state of the battery pack based on the closed curve.

### CROSS-REFERENCE TO RELATED PATENT APPLICATION

This application claims priority to and the benefit of Chinese Patent Application No. 202210095433.4, both filed Jan. 26, 2022, which are incorporated herein in their entireties by reference.

### FIELD OF THE INVENTION

The invention relates generally to the field of data analysis, and more particularly to methods, systems and terminal devices for analyzing states of battery packs in a battery cluster.

### BACKGROUND OF THE INVENTION

At present, a large number of batteries are used in energy storage power stations and new energy vehicles. Different manufacturers, different manufacturing processes, and different operating conditions may inevitably cause inconsistency in battery packs. In actual use, the charge and discharge control of the battery pack is determined by the cells with the worst charge and discharge performance, and the inconsistency may affect the safe operation of the energy storage power stations and new energy vehicles, and even causes safety hazards. In order to ensure the safety of the battery packs in long-term use, it is necessary to continuously monitor and analyze the operating data of the battery packs. It is particularly important to find those cells and battery packs that appear inconsistent in time.

In the prior art, for different batteries in the same battery pack, the distribution of data in the battery pack can be determined and whether the battery pack is normal or not can be determined by calculating the discrete situation of the voltage standard score of the batteries. But for battery clusters, there is currently no good way to visually check the status of each battery pack in the cluster. This is because the battery packs are connected in series during charging and discharging, so the worst performing cell in each battery pack will affect the overall performance of the battery cluster. During the charge and discharge process, the worst-performing single cells are the first to reach the cut-off voltage. In theory, replacing the worst single cells can increase the capacity of the entire battery pack. In fact, a single cell cannot be replaced alone, and the smallest unit that can be directly replaced is the battery pack.

Therefore, it is particularly important to find out the worst-performing battery pack during the charging and discharging process.

### SUMMARY OF THE INVENTION

In view of the aforementioned deficiencies and inadequacies in the prior art, one of the objectives of this invention is to provide a method, a system and a terminal device for analyzing states of battery packs in a battery cluster, which can evaluate the working status of each battery pack in the battery cluster based on the voltage information of the battery, and effectively improve the effectiveness and safety of the battery cluster.

In one aspect of the invention, the method includes acquiring cell voltages of each battery pack in the battery cluster within a preset time; performing data cleaning on the acquired cell voltages; calculating a voltage standard score of each cell based on the cell voltages after data cleaning; calculating a mean value and a standard deviation of said voltage standard score; for each battery pack, plotting scattered points based on the mean value and the standard deviation, and performing closed curve fitting to the scattered points to obtain a closed curve; and analyzing the state of the battery pack based on the closed curve.

In one embodiment, said calculating the voltage standard score of each cell based on the cell voltage after data cleaning comprises: calculating the mean or median value μ_{c} and the standard deviation σ_{c} of the cell voltage after data cleaning within the preset time; and calculating the voltage standard score

$${S}_{i} = \frac{{V}_{i} - {μ}_{c}}{{σ}_{c}}$$

of each cell, where Vᵢ represents the voltage value of the i-th cell in the battery pack.

In one embodiment, for each battery pack, said plotting the scatter points based on the mean value and the standard deviation comprises establishing a coordinate system with the mean value and the standard deviation as horizontal and vertical coordinates, respectively; and based on the mean value and the standard deviation of the voltage standard score of each cell in the battery pack, plotting the scatter points corresponding to the cells one by one in the coordinate system.

In one embodiment, said performing the closed curve fitting on the scattered points comprises performing the closed curve fitting to the scattered points based on the smallest circumscribed circle; performing the closed curve fitting to the scattered points based on the smallest circumscribed rectangle; or performing the closed curve fitting to described scatter point based on the smallest circumscribed polygon.

In one embodiment, said analyzing the state of the battery pack comprises setting a threshold, and when the closed curve exceeds the threshold, it is determined that the corresponding battery pack is abnormal.

In one embodiment, the method also includes issuing an early warning when it is determined that the battery pack is abnormal.

In another aspect of the invention, the system includes an acquisition module, a cleaning module, a first calculation module, a second calculation module, a fitting module and an analysis module.

The acquisition module is configured to acquire cell voltages of each battery pack in the battery cluster within a preset time.

The cleaning module is configured to perform data cleaning of the acquired cell voltages.

The first calculation module is configured to calculate a voltage standard score of each cell based on the cell voltages after data cleaning.

The second calculation module is configured to calculate a voltage standard score of each cell based on the cell voltages after data cleaning.

The fitting module is configured to plot scattered points based on the mean value and the standard deviation for each battery pack, and perform closed curve fitting on the scattered points to obtain a closed curve.

The analysis module is configured to analyze the state of the battery pack based on the closed curve.

In yet another aspect of the invention, the terminal device includes a processor and a memory. The said memory is used to store computer programs. Said processor is used to execute the computer program stored in the memory, so that a terminal device executes the method for battery pack state analysis in the battery cluster as disclosed above.

In view of the foregoing, the method, system and terminal device for analyzing states of battery packs in a battery cluster have the following advantageous effects.

(1) By analyzing the voltage data of the battery and using methods such as fitting the smallest circumscribed circle, the smallest circumscribed rectangle, and the smallest circumscribed polygon, the states of each battery pack in the battery cluster can be effectively monitored and analyzed.

(2) Whether the battery pack is normal or not can be accurately determined, and a timely warning of the problematic battery pack can be issued.

(3) A theoretical basis is provided for increasing the capacity by replacing the battery pack.

### BRIEF DESCRIPTION OF THE DRAWINGS

FIG. 1 shows schematically a flowchart of a method for analyzing the state of the battery packs in the battery cluster according to one embodiment of the invention.

FIG. 2 shows a schematic diagram of the fitting smallest circumscribed circle of a battery pack according to one embodiment of the invention.

FIG. 3 shows a schematic diagram schematic diagram of the fitting smallest circumscribed rectangle of a battery pack according to one embodiment of the invention.

FIG. 4 shows a schematic diagram of the fitting smallest circumscribed polygon of a battery pack according to one embodiment of the invention.

FIG. 5 shows a schematic diagram of the fitting smallest circumscribed circle of each battery pack in the battery cluster according to one embodiment of the invention.

FIG. 6 shows a schematic diagram of the fitting smallest circumscribed rectangle of each battery pack in the battery cluster according to one embodiment of the invention.

FIG. 7 shows a schematic diagram of the fitting smallest circumscribed polygon of each battery pack in the battery cluster according to one embodiment of the invention.

FIG. 8 shows schematically a structural diagram of a system for analyzing the state of the battery packs in the battery cluster according to one embodiment of the invention.

FIG. 9 is schematically a structural diagram of a terminal device for analyzing the state of the battery packs in the battery cluster according to one embodiment of the invention.

### DETAILED DESCRIPTION OF THE INVENTION

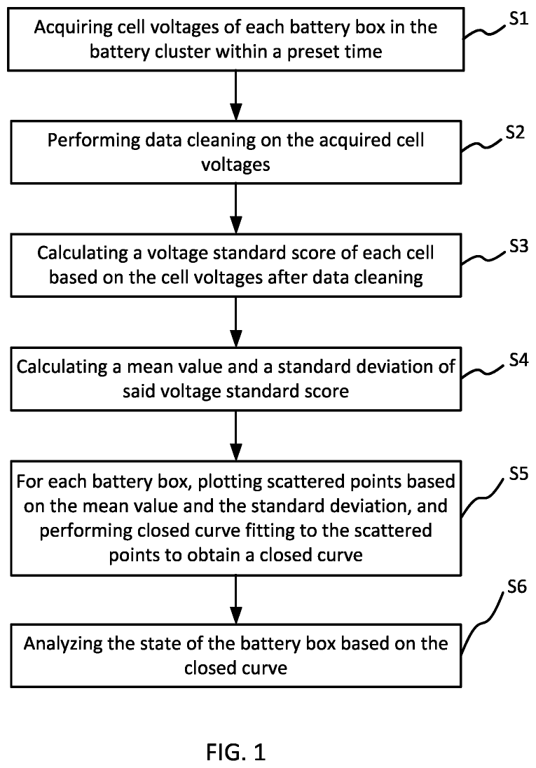

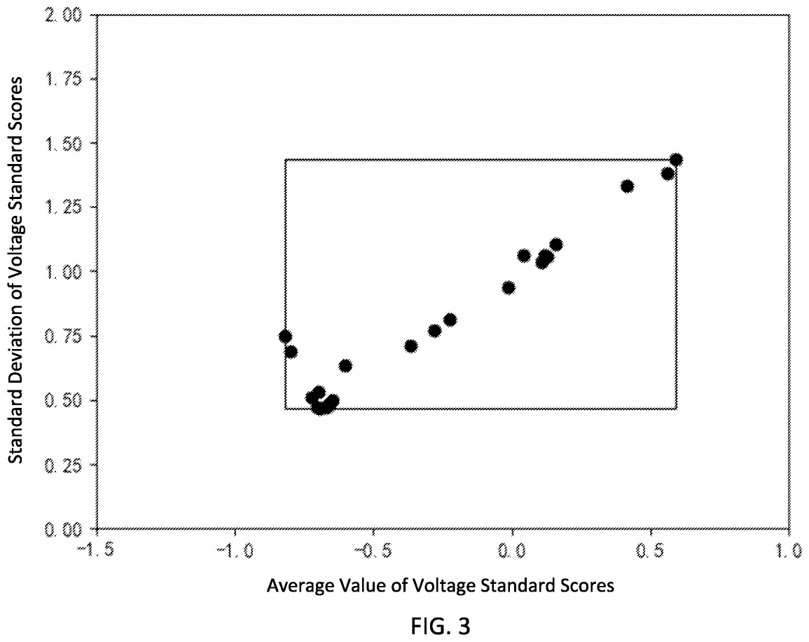

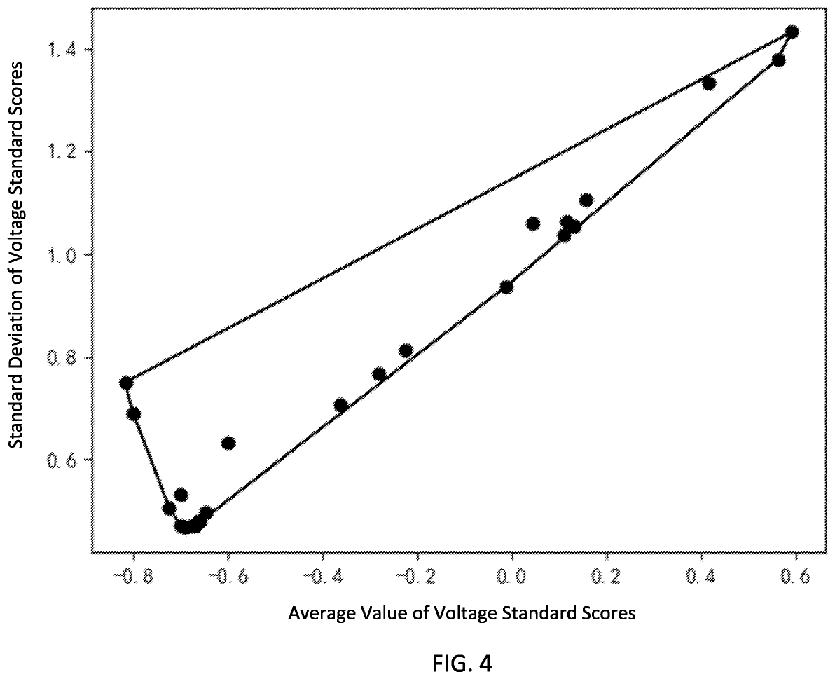

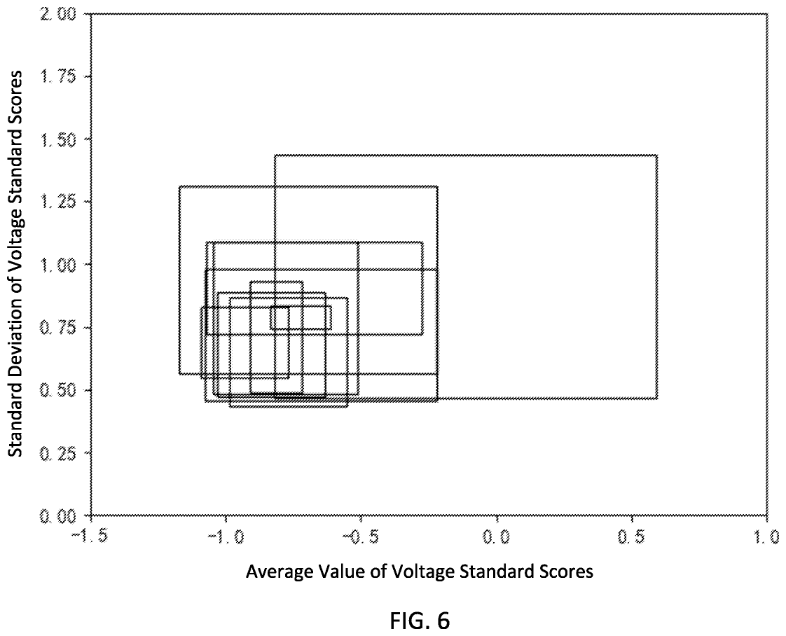

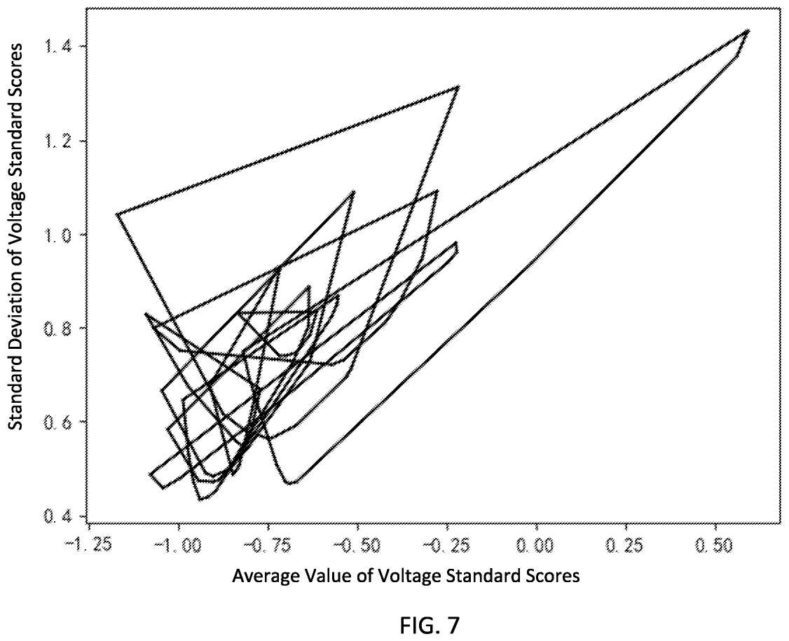

Embodiments of the invention are described below through specific examples in conjunction with the accompanying drawings in FIGS. 1-9, and those skilled in the art can easily understand other advantages and effects of the invention from the content disclosed in this specification. The invention can also be implemented or applied through other different specific implementations, and various modifications or changes can be made to the details in this specification based on different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. Dimensional drawing, the type, quantity and proportion of each component can be changed arbitrarily in its actual implementations. More complicate component layouts may also become apparent in view of the drawings, the specification, and the following claims.

In accordance with the purposes of the invention, as embodied and broadly described herein, this invention, in certain aspects, relates to a method, a system and a terminal device for analyzing states of battery packs in a battery cluster by analyzing the cell voltage information of the battery packs in the battery cluster, with no need of professional equipment and disassembling the battery cluster, which can effectively improve the safety, efficacy and life of the battery cluster.

It should be noted that as used herein, the terms, “battery module” and “battery pack” are exchangeable and each of which refers to a battery assembly including a plurality of battery cells electrically coupled to each other in series and in parallel; and the terms, “battery”, “battery cell” and “cell” are exchangeable and each of which refers to a single electrochemical cell/unit that converts the chemical energy into electrical energy. The plurality of battery cells are generally connected in series/parallel to form a battery pack; multiple battery packs are connected in series to form a battery cluster; and various battery clusters are connected in parallel to form a battery stack.

Referring to FIG. 1, the method for analysis states of battery packs in a battery cluster is shown according to one embodiment of the invention. The method includes the following steps.

As step S1, acquiring the cell voltage of each battery pack in the battery cluster within a preset time.

Specifically, within a preset time, such as one month, one week, two days, 24 hours, etc., the voltage value of each single cell of each battery pack in the battery cluster is acquired.

At step S2, performing data cleaning on the acquired cell voltage of each cell of each battery pack.

Specifically, data cleaning is the process of re-examining and verifying data, with the purpose of deleting duplicate information, correcting existing errors, and providing data consistency. Therefore, in order to ensure the validity of the acquired cell voltage, data cleaning operations are performed to eliminate abnormal data and missing data.

At step S3, calculating the voltage standard score of each cell based on the cell voltage after data cleaning.

Specifically, said calculating the voltage standard score of each cell based on the cell voltage after data cleaning includes calculating the mean or median value μ_{c} and the standard deviation σ_{c} of the cell voltage after data cleaning within the preset time; and calculating the voltage standard score

$${S}_{i} = \frac{{V}_{i} - {μ}_{c}}{{σ}_{c}}$$

of each cell, where Vᵢ represents the voltage value of the i-th cell in the battery pack.

In one embodiment, after the voltage standard score of each cell is calculated, the median or average value of the voltage standard score of the cell within the preset time is calculated. When | the median or average value of the voltage standard score|< a first threshold value, it is determined that the cell is in a healthy state; when the first threshold value ≤| the median or average value of the voltage standard score|< a second threshold value, it is determined that inconsistency occurs in the battery cell; when the second threshold value ≤| the median or average value of the voltage standard score|< a third threshold value, it is determined that the inconsistency of the cell begins getting worsen; when the third threshold value ≤| the median or average value of the voltage standard score|, it is determined that it is necessary to intervene in the inconsistency of the battery cell. In certain embodiments, the first threshold value, the second threshold value and the third threshold value may be set according to actual application scenarios. Ideally, the voltage standard score of each cell in the battery pack should be 0. However, due to differences in manufacturing processes and operating conditions, the voltage standard score of each single cell may be different in actual situations, so the battery cell with poor performance inside the battery pack can be screened based on the voltage standard score of the battery cell. It should be noted that used herein, the terms, “| A|” represents an absolute value of A; “A<B” represents that A is less than B; and “A≤B” represents that A is equal to or less than B.

At step S4, calculating the mean or average value and the standard deviation of the voltage standard score based on the voltage standard score.

Specifically, for each single cell, the corresponding mean value and standard deviation for the voltage standard score obtained within the preset time can be calculated, so that the voltage standard score of multiple values can be integrated into one value to represent the cell.

At step S5, for each battery pack, plotting scatter points based on the mean value and the standard deviation, and performing closed curve fitting on the scatter points to obtain a closed curve.

Specifically, for each battery cell in each battery pack, scatter points are plotted according to the mean value and the standard deviation of the corresponding voltage standard score, so as to obtain the distribution of the scatter points, which is used to determine the operation state of said battery pack.

In one embodiment, for each battery pack, said plotting the scatter points based on the mean value and the standard deviation includes establishing a coordinate system with the mean vale and the standard deviation as the horizontal and vertical coordinates, respectively; and based on the mean value and the standard deviation of the voltage standard score of each cell in the battery pack, plotting the scatter points corresponding to the cells one by one in the coordinate system.

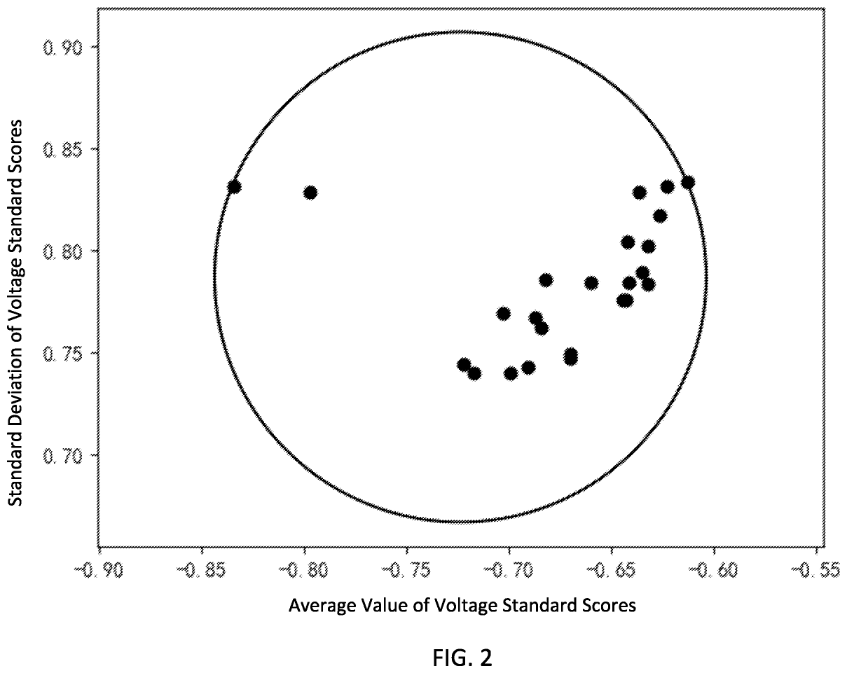

Then, the closed curve is fitted to the scattered points obtained above. In some embodiments, the closed curve fitting process is performed based on any one of the smallest circumscribed circle, the smallest circumscribed rectangle and the smallest circumscribed polygon, as shown in FIGS. 2-4.

At step S6, analyzing the state of each battery pack based on the closed curve obtained by fitting.

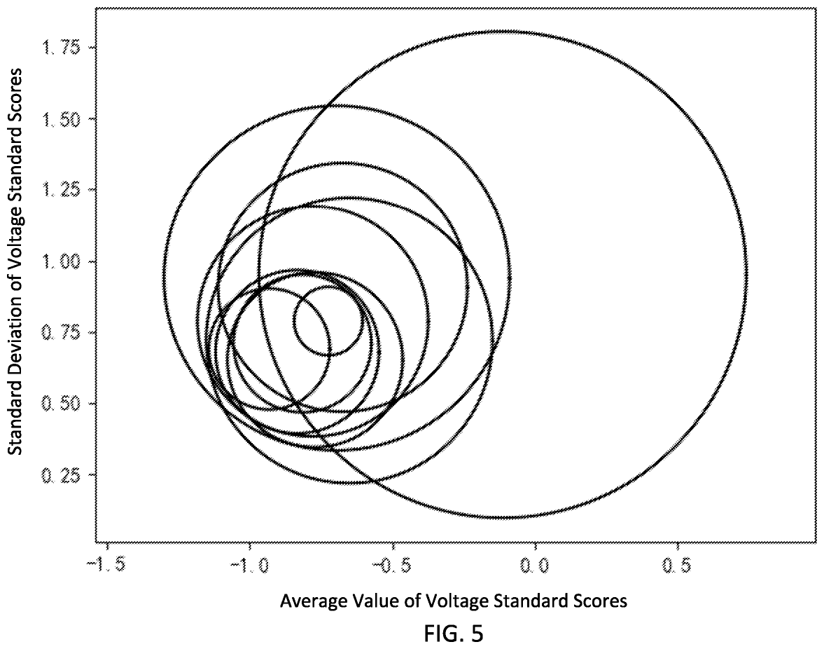

Specifically, according to the closed curve, as shown in FIG. 5-7, by comparing the states of each battery pack in the battery cluster, the battery pack in a normal state or an abnormal state can be analyzed. For example, a battery pack corresponding to a closed curve that deviates from most of the closed curves is in an abnormal state.

In one embodiment, different judgment thresholds are set for different curve fitting methods. The state of the corresponding battery pack is determined according to the threshold interval where the closed curve is located. When it is determined that the corresponding battery pack is abnormal, an early warning is issued in time so as to provide support for battery pack replacement. For example, the abscissa of the closed curve represents the mean value of the voltage standard score, a first threshold value, a second threshold value and a third threshold value are set. When | the median or average value of the voltage standard score |< the first threshold value, it is judged that the battery pack is in a healthy state; when the first threshold value ≤| the median or average value of the voltage standard score|< the second threshold value, it is judged that the battery pack has inconsistency; when the second threshold value ≤| the median or average value of the voltage standard score|< the third threshold value, it is judged that the inconsistency of the battery pack begins to deteriorate; and when the third threshold values ≤| the median or average value of the voltage standard score|, it is determined that the inconsistency of the battery pack needs to be intervened.

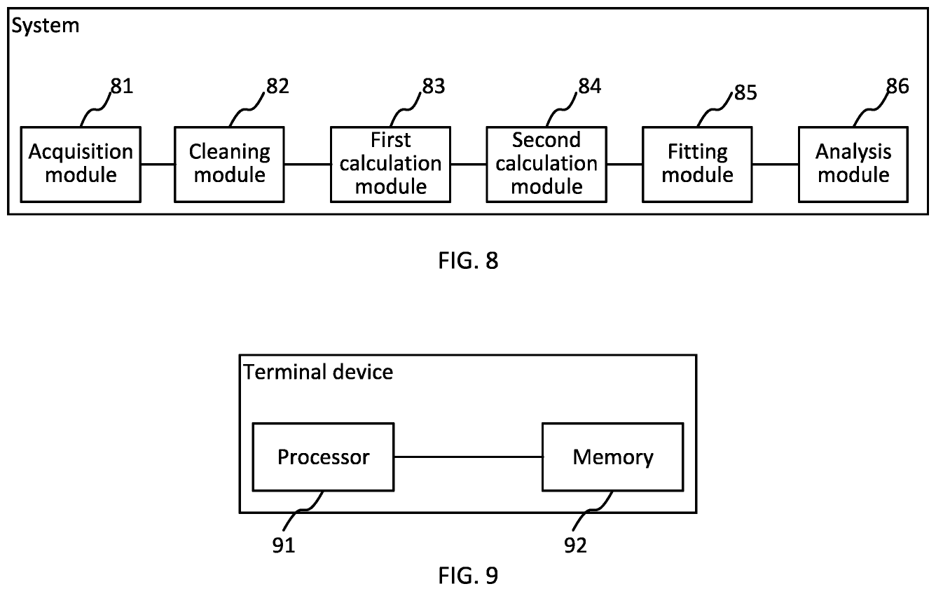

FIG. 8 shows one embodiment of the system for the battery pack state analysis in the battery cluster. The system includes an acquisition module 81, a cleaning module 82, a first calculation module 83, a second calculation module 84, a fitting module 85 and analysis module 86.

The acquisition module 81 is configured to acquire the cell voltage of each battery pack in the battery cluster within a preset time. For example, the acquisition module 81 in one embodiment may include one or more voltage meters for measuring these voltages.

The cleaning module 82 is connected to the acquisition module 81 and configured to perform data cleaning of the acquire cell voltage of each battery pack.

The first calculation module 83 is connected to the cleaning module 82 and configured to calculate the voltage standard score of each cell based on the cell voltage after data cleaning.

The second calculation module 84 is connected to the first calculation module 83 and configured to calculate the mean value and the standard deviation of the voltage standard score.

The fitting module 85 is connected with the second calculation module 84, and configured to plot scattered points based on the mean value and the standard deviation for each battery pack, and performing closed curve fitting on the scattered points to obtain a closed curve.

The analysis module 86 is connected to the fitting module 85 and configured to analyze the state of the battery pack based on the closed curve obtained by fitting.

The structures and principles of the acquisition module 81, the cleaning module 82, the first calculation module 83, the second calculation module 84, the fitting module 85 and the analysis module 86 are in one-to-one correspondence with the steps in the above-mentioned battery pack state analysis method in the battery cluster, so they are not repeated herein.

It should be noted that each of the acquisition module 81, the cleaning module 82, the first calculation module 83, the second calculation module 84, the fitting module 85 and the analysis module 86 of the system/apparatus is disclosed only in accordance with to its logical functions, and may be fully or partially integrated into one physical entity or physically separated during actual implementation. Moreover, these modules can be implemented in the form of calling software through processing elements, or can be implemented in the form of hardware, or some modules can be implemented in the form of calling software through processing elements, and some modules can be implemented in the form of hardware. For example, the x module can be a separate processing element, and can also be integrated in a chip of the above-disclosed system/apparatus. In addition, the x module can also be stored in the memory of the above-disclosed system/apparatus in the form of program codes, and can be invoked by certain processing elements of the above-disclosed system/apparatus to execute the functions of the x module. The implementation of other modules is similar. All or part of these modules can be integrated together, and can also be implemented independently. The processing elements mentioned here may be an integrated circuit with signal processing capability. In the implementation process, each step of the above disclosed method or each module above can be completed by an integrated logic circuit of hardware in the processor element or an instruction in the form of software. The above modules may be one or more integrated circuits configured to implement the above method, for example: one or more application specific integrated circuit (ASIC), one or more microprocessors (e.g., digital signal processor, DSP), one or more field programmable gate array (FPGA), etc. When one of the above modules is implemented in the form of a processing element scheduling program codes, the processing element may be a general-purpose processor, such as a central processing unit (CPU) or other processors that can call program codes. These modules can be integrated together and realized in the form of System-on-a-chip (SOC).

In one embodiment, the computer programs are stored on the storage medium, and when the program is executed by the processor, the above voltage-based battery pack state analysis method is realized. In one embodiment, the storage medium includes various media capable of storing program codes such as ROM, RAM, magnetic disk, U disk, memory card, or optical disk.

As shown in FIG. 9, in one embodiment, the terminal device for battery pack state analysis in the battery cluster includes a processor 91 and a memory 92.

The memory 92 is used to store computer programs. The memory 92 may include various media that can store program codes such as ROM, RAM, magnetic disk, U disk, memory card or optical disk.

The processor 91 is connected to the memory 92, and used to execute the computer program stored in the memory, so that the terminal device executes the method for battery pack state analysis in the battery cluster as described above.

In certain embodiments, the processor can be a general-purpose processor, including a central processing unit (CPU), or a network processor (NP), etc. It can also be a digital signal processor (DSP), application specific integrated circuit (ASIC), field programmable gate array (FPGA), or other programmable logic devices, discrete gate or transistor logic devices, discrete hardware components.

Briefly, the method, system and terminal for analyzing the state of the battery pack in the battery cluster of the present invention can effectively monitor and analyze the status of each battery pack in the battery cluster, by analyzing the voltage data of the battery and using methods such as fitting the smallest circumscribed circle, the smallest circumscribed rectangle, and the smallest circumscribed polygon. It can accurately determine whether the battery pack is normal or not, issue a timely warning of the problematic battery pack; and provide a theoretical basis for increasing the capacity by replacing the battery pack. Therefore, the present invention effectively overcomes various shortcomings in the prior art and has high industrial application value.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for analyzing states of battery packs in a battery cluster, comprising:
acquiring cell voltages of each battery pack in the battery cluster within a preset time;
performing data cleaning on the acquired cell voltages;
calculating a voltage standard score of each cell based on the cell voltages after data cleaning;
calculating a mean value and a standard deviation of said voltage standard score;
for each battery pack, plotting scattered points based on the mean value and the standard deviation, and performing closed curve fitting to the scattered points to obtain a closed curve; and
analyzing the state of the battery pack based on the closed curve;
wherein said calculating the voltage standard score of each cell based on the cell voltage after data cleaning comprises:
calculating the mean or median value μ_{c} and the standard deviation σ_{c} of the cell voltage after data cleaning within the preset time; and
calculating the voltage standard score
$${S}_{i} = \frac{{V}_{i} - {μ}_{c}}{{σ}_{c}}$$
of each cell, where Vᵢ represents the voltage value of the i-th cell in the battery pack;
wherein for each battery pack, said plotting the scatter points based on the mean value and the standard deviation comprises:
establishing a coordinate system with the mean value and the standard deviation as horizontal and vertical coordinates, respectively; and
based on the mean value and the standard deviation of the voltage standard score of each cell in the battery pack, plotting the scatter points corresponding to the cells one by one in the coordinate system;
wherein said performing the closed curve fitting on the scattered points comprises:
performing the closed curve fitting to the scattered points based on the smallest circumscribed circle;
performing the closed curve fitting to the scattered points based on the smallest circumscribed rectangle; or
performing the closed curve fitting to described scatter point based on the smallest circumscribed polygon;
wherein said analyzing the state of the battery pack comprise:
setting a threshold, and when the closed curve exceeds the threshold, it is determined that the corresponding battery pack is abnormal.

2. The method according to claim 1, further comprising issuing an early warning when it is determined that the battery pack is abnormal.

3. A system for analyzing states of battery packs in a battery cluster, comprising:
an acquisition module, a cleaning module, a first calculation module, a second calculation module, a fitting module and an analysis module, wherein:
the acquisition module is configured to acquire cell voltages of each battery pack in the battery cluster within a preset time;
the cleaning module is configured to perform data cleaning of the acquired cell voltages;
the first calculation module is configured to calculate a voltage standard score of each cell based on the cell voltages after data cleaning;
the second calculation module is configured to calculate a voltage standard score of each cell based on the cell voltages after data cleaning;
the fitting module is configured to plot scattered points based on the mean value and the standard deviation for each battery pack, and perform closed curve fitting on the scattered points to obtain a closed curve; and
the analysis module is configured to analyze the state of the battery pack based on the closed curve;
wherein said calculating the voltage standard score of each cell based on the cell voltage after data cleaning comprises:
calculating the mean or median value μ_{c} and the standard deviation σ_{c} of the cell voltage after data cleaning within the preset time; and
calculating the voltage standard score
$${S}_{i} = \frac{{V}_{i} - {μ}_{c}}{{σ}_{c}}$$
of each cell, where Vᵢ represents the voltage value of the i-th cell in the battery pack;
wherein for each battery pack, said plotting the scatter points based on the mean value and the standard deviation comprises:
establishing a coordinate system with the mean value and the standard deviation as horizontal and vertical coordinates, respectively; and
based on the mean value and the standard deviation of the voltage standard score of each cell in the battery pack, plotting the scatter points corresponding to the cells one by one in the coordinate system;
wherein said performing the closed curve fitting on the scattered points comprises:
performing the closed curve fitting to the scattered points based on the smallest circumscribed circle;
performing the closed curve fitting to the scattered points based on the smallest circumscribed rectangle; or
performing the closed curve fitting to described scatter point based on the smallest circumscribed polygon;
wherein said analyzing the state of the battery pack comprise:
setting a threshold, and when the closed curve exceeds the threshold, it is determined that the corresponding battery pack is abnormal

4. A terminal device for analyzing states of battery packs in a battery cluster, comprising:
a processor, and a memory,
wherein said memory is used to store computer programs; and
wherein said processor is used to execute the computer program stored in the memory, so that a terminal device executes the method for battery pack state analysis in the battery cluster according to claim 1.
